(19) United States
(12) Patent Application Publication
(10) Pub. No.: US 2025/0079185 A1
(43) Pub. Date: Mar. 6, 2025

(54) METHOD OF BONDING SEMICONDUCTOR MATERIALS AND STRUCTURE FORMED BY THE SAME

(71) Applicant: National Yang Ming Chiao Tung University, Hsinchu City (TW)

(72) Inventor: Seiji Samukawa, Hsinchu City (TW)

(21) Appl. No.: 18/239,143

(22) Filed: Aug. 29, 2023

(51) Int. Cl. H01L 21/324

(52) U.S. Cl. CPC H01L 21/324

(57) ABSTRACT

The present inventive concept discloses a method of bonding two pieces of semiconductor materials, which comprises: providing the two pieces of semiconductor materials each having a surface that is suitable for molecular bonding; and activating at least one surface monolayer of one of the two pieces of semiconductor materials by irradiating neutral beam onto the surface(s) being activated while controlling activation parameters of the neutral beam to provide kinetic energy to the pieces sufficient to create an activated region of controlled thickness beneath the surface(s) being activated.

### BACKGROUND OF THE INVENTION

### 1. Field of the Invention

The present disclosure generally relates to semiconductor processing, particularly, to a heterogeneous bonding technology at low temperatures. The present disclosure also relates to a bonded semiconductor structure formed by the bonding method of the present inventive concept.

### 2. Description of the Related Art

As the semiconductor industry faces fundamental challenges in device scaling, it becomes necessary to explore alternative and various materials and device structures. Three-dimensional integrated circuits can be realized by stacking different semiconductors by bonding, which improves circuit performance and circuit functionality.

To achieve the requirements of the semiconductor industry, the bonding process must meet some criteria. The bonding process should provide defect-free bonded interfaces, high bond strength, and scalability.

Conventional bonding approach, such as plasma bonding, is achieved by annealing at high temperature, e.g. higher than 700° C. However, while ultra-miniature nanoscale devices are expected to be prevalent in the near future, plasma bonding processes can cause some severe issues and affect the electrical, optical, spintronic, and thermodynamic properties due to process-induced defects. High temperature bonding (>700° C.) are not suitable for heterogeneous layered structures due to (<700° C.) low thermal budget requirement.

However, bonding layers at low temperatures can result in bonded interfaces with low surface energies, which limits the subsequent process. Even high surface energies for direct bonding between Si wafers can be achieved at low temperature, but the bonded interfaces displayed voids and defects.

There is a need for providing a low temperature binding process of layered structure semiconductors with bonding interfaces that have low defect density.

### SUMMARY OF THE INVENTION

In light of solving the foregoing problems of the prior art, the present inventive concept provides a method of bonding two pieces of semiconductor materials. The method comprises providing the two pieces of semiconductor materials each having a surface that is suitable for molecular bonding; and activating at least one surface monolayer of one of the two pieces of semiconductor materials by irradiating neutral beam onto the surface(s) being activated while controlling activation parameters of the neutral beam to provide kinetic energy to the pieces sufficient to create an activated region of controlled thickness beneath the surface(s) being activated.

According to an embodiment of the present inventive concept, the surface monolayer of each piece of semiconductor materials is activated by the neutral beam.

According to an embodiment of the present inventive concept, the two pieces of semiconductor materials are made of different semiconductor materials.

According to an embodiment of the present inventive concept, the controlling of the activation parameters obtains the activation of the surface(s) and creates the activated region in a predetermined thickness of the activated surface(s) and serves to control the maximum depth of the activated region in the surfaces.

According to an embodiment of the present inventive concept, wherein the activated region extends in the predetermined thickness of the piece(s) of semiconductor materials whose surface is being activated between a depth of 0.1 nm to 1 nm.

According to an embodiment of the present inventive concept, the kinetic energy provided by the neutral beam is at a level of 10 eV to 200 eV.

According to an embodiment of the present inventive concept, the controlling of the activation parameters comprises controlling kinetic energy by controlling plasma generation power and aperture bias power for the neutral beam to the surface(s) of the piece(s) of semiconductor materials.

According to an embodiment of the present inventive concept, the controlling of the activation parameters comprises controlling kinetic energy by controlling the plasma generation power in a range between 500 W to 1500 W.

According to an embodiment of the present inventive concept, the controlling of the activation parameters comprises controlling kinetic energy by controlling the aperture bias power in a range between 0 W to 30 W.

According to an embodiment of the present inventive concept, the controlling of the activation parameters comprises controlling a composition of gas in which the neutral beam is generated to provide a desired kinetic energy.

According to an embodiment of the present inventive concept, the gas is at least one selected from a group consisting of oxygen, nitrogen, hydrogen, and rare gas.

According to an embodiment of the present inventive concept, the rare gas comprises argon, xenon, or krypton.

According to an embodiment of the present inventive concept, the controlling of the activation parameters comprises controlling the composition of gas passing an aperture plate to generate neutral beam.

According to an embodiment of the present inventive concept, the aperture plate has an aperture aspect ratio which is more than 10.

According to an embodiment of the present inventive concept, the aperture plate has a size of 1 mm×10 mm.

According to an embodiment of the present inventive concept, the controlling of the activation parameters comprises controlling the composition of gas at a pressure of 0.1 Pa to 1 Pa for the neutral beam to provide a desired kinetic energy.

According to an embodiment of the present inventive concept, the controlling of the activation parameters is implemented in order to create a single activated region in a predetermined thickness of the surface region of the piece(s) of semiconductor materials whose surface is being activated.

According to the present inventive concept, the method further comprises: introducing the activated surfaces to contact to each other.

According to an embodiment of the present inventive concept, the activated surfaces contact to each other at a temperature of no higher than about 200° C.

According to an embodiment of the present inventive concept, the temperature is from about 100° C. to 200° C.

According to the present inventive concept, the method further comprises: conducting wet surface modification at least on the surface(s) of the two pieces of semiconductor materials before the step of activating at least one surface monolayer of one of the two pieces of semiconductor materials by irradiating neutral beam onto the surface(s).

The present inventive concept provides a structure formed according to the method of the present inventive concept.

Compared to the conventional bonding approach, such as plasma bonding, is achieved by annealing at high temperature, the method of the present inventive concept provides a method enabling the bonding of two pieces of semiconductor materials at low temperature, such as room temperature to no higher than 200° C. The present inventive concept is able to fabricate a bonded layered heterogeneous semiconductor structure without defects at the bonding interface, which makes high-quality heterogeneous integrated semiconductor structure possible.

### BRIEF DESCRIPTION OF THE DRAWINGS

FIG. 1 is a flowchart of an embodiment of the method of the present inventive concept;

FIG. 2 is a flowchart of another embodiment of the method of the present inventive concept;

FIG. 3 shows the comparison of some characteristics of an embodiment of the method of the present inventive concept and those of the comparative example; and

FIG. 4 is a graph showing the surface energy of an embodiment of the method of the present inventive concept and that of the comparative example at different temperature.

### DETAILED DESCRIPTION

The present inventive concept is described by the following specific embodiments. Those with ordinary skills in the arts can readily understand other advantages and functions of the present inventive concept after reading the disclosure of this specification. Any changes or adjustments made to their relative relationships, without modifying the substantial technical contents, are also to be construed as within the range implementable by the present inventive concept.

Moreover, the word “exemplary” or “embodiment” is used herein to mean serving as an example, instance, or illustration. Any aspect or design described herein as exemplary or an embodiment is not necessarily to be construed as preferred or advantageous over other aspects or designs. Rather, use of the word “exemplary” or “embodiment” is intended to present concepts and techniques in a concrete fashion.

As used in this application, the term “or” is intended to mean an inclusive “or” rather than an exclusive “or.” That is, unless specified otherwise or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more,” unless specified otherwise or clear from context to be directed to a singular form.

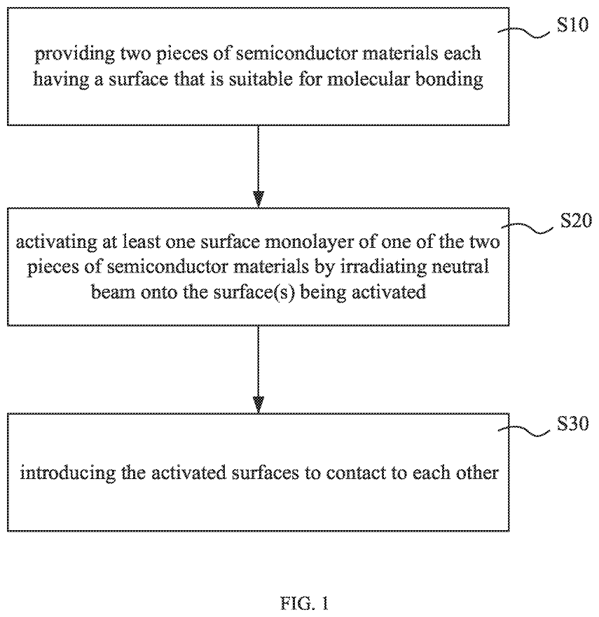

Please refer to FIG. 1 which is a flow chart of the method of the present inventive concept. In a first aspect, the present inventive concept provides a method of bonding two pieces of semiconductor materials.

The method of the present inventive concept comprises

S10. providing the two pieces of semiconductor materials each having a surface that is suitable for molecular bonding; and

S20. activating at least one surface monolayer of one of the two pieces of semiconductor materials by irradiating neutral beam onto the surface(s) being activated while controlling activation parameters of the neutral beam to provide kinetic energy to the pieces sufficient to create an activated region of controlled thickness beneath the surface(s) being activated.

In an embodiment of the present inventive concept, the surface monolayer of each piece of semiconductor materials may be activated by the neutral beam.

In a preferable embodiment of the present inventive concept, the two pieces of semiconductor materials may be made of different semiconductor materials.

In an embodiment of the present inventive concept, the controlling of the activation parameters may obtain the activation of the surface(s) and create the activated region in a predetermined thickness of the activated surface(s) and serve to control the maximum depth of the activated region in the surfaces.

In an embodiment of the present inventive concept, the activated region may extend in the predetermined thickness of the piece(s) of semiconductor materials whose surface is being activated between a depth of 0.1 nm to 1 nm.

In an embodiment of the present inventive concept, the kinetic energy provided by the neutral beam may be at a level of 10 eV to 200 eV.

In an embodiment of the present inventive concept, the controlling of the activation parameters may comprise controlling kinetic energy by controlling plasma generation power and aperture bias power for the neutral beam to the surface(s) of the piece(s) of semiconductor materials.

In an embodiment of the present inventive concept, the controlling of the activation parameters may comprise controlling kinetic energy by controlling the plasma generation power in a range between 500 W to 1500 W.

In an embodiment of the present inventive concept, the controlling of the activation parameters may comprise controlling kinetic energy by controlling the aperture bias power in a range between 0 W to 30 W.

In an embodiment of the present inventive concept, the controlling of the activation parameters may comprise controlling a composition of gas in which the neutral beam is generated to provide a desired kinetic energy.

In an embodiment of the present inventive concept, the gas may be for example, at least one selected from a group consisting of oxygen, nitrogen, hydrogen, and rare gas.

The rare gas may comprise argon, xenon, krypton, or the like.

In an embodiment of the present inventive concept, the controlling of the activation parameters may comprise controlling the composition of gas passing an aperture plate to generate neutral beam.

In an embodiment of the present inventive concept, the aperture plate may have a desired physical characteristics, such as an aperture aspect ratio which may be more than 10.

Preferably, the aperture plate may have a size of 1 mm×10 mm.

In an embodiment of the present inventive concept, the controlling of the activation parameters may comprise controlling the composition of gas at a pressure of 0.1 Pa to 1 Pa for the neutral beam to provide a desired kinetic energy.

In an embodiment of the present inventive concept, the controlling of the activation parameters may be implemented in order to create a single activated region in a desired or predetermined thickness of the surface region of the piece(s) of semiconductor materials whose surface is being activated.

Further refer to FIG. 1. According to the present inventive concept, the method may further comprise:

S30. introducing the activated surfaces to contact to each other.

In an embodiment of the present inventive concept, the activated surfaces may contact to each other at a temperature of no higher than about 200° C.

In a preferable embodiment of the present inventive concept, the temperature is from about 100° C. to 200° C.

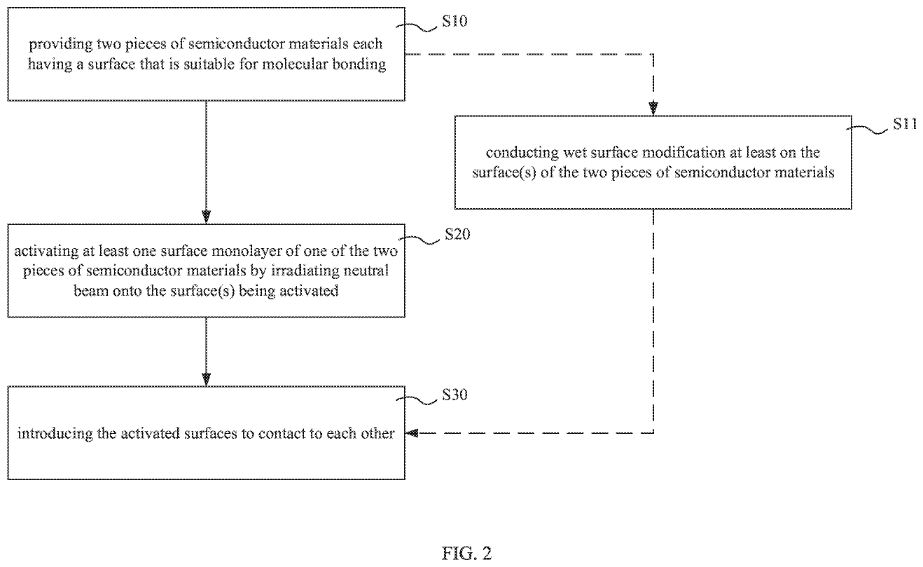

Please refer to FIG. 2 which is a flowchart of another embodiment of the method of the present inventive concept. According to the present inventive concept, the method may further comprise:

S11. conducting wet surface modification at least on the surface(s) of the two pieces of semiconductor materials before the step of activating at least one surface monolayer of one of the two pieces of semiconductor materials by irradiating neutral beam onto the surface(s).

In a second aspect, the present inventive concept provides a structure formed according to the method of the present inventive concept.

The following examples are provided to illustrate the present inventive concept as well as some advantages obtained therefrom.

### Example 1

In this example, bonded pieces of semiconductor materials were prepared utilizing the method of the present inventive concept.

First, a neutral beam generation system is provided. The neutral beam generation system is divided into a plasma chamber and a process chamber by an aperture plate therebetween.

two pieces of semiconductor materials each having a surface that is suitable for molecular bonding are put in the process chamber.

Please note that the pieces of semiconductor materials are made of different material in Example 1.

Then, each of the surface of the two pieces of semiconductor materials is irradiated by neutral beam to make the surfaces activated.

According to the present inventive concept, the controlling activation parameters of the neutral beam may provide kinetic energy to the pieces sufficient to create an activated region of controlled thickness beneath the surface(s) being activated. In Example 1, the kinetic energy provided by the neutral beam is at a level of 10 eV to 200 eV.

The controlling of the activation parameters obtains the activation of the surface(s) and create the activated region in a predetermined thickness of the activated surface(s) and serve to control the maximum depth of the activated region in the surfaces. In Example 1, the activated region extends in the predetermined thickness of the pieces of semiconductor materials whose surface is being activated between a depth of 0.1 nm to 1 nm.

According to the present inventive concept, the desired kinetic energy is controlled by controlling plasma generation power and aperture bias power for the neutral beam to the surfaces of the pieces of semiconductor materials.

In Example 1, the plasma generation power is controlled in a range between 500 W to 1500 W and the aperture bias power is controlled in a range between 0 W to 30 W.

According to the present inventive concept, a composition of gas is controlled in which the neutral beam is generated to provide a desired kinetic energy.

In Example 1, the composition of gas may be introduced into the plasma chamber. The gas may be for example, at least one selected from a group consisting of oxygen, nitrogen, hydrogen and rare gas.

The rare gas may comprise argon, xenon, krypton, or the like.

In Example 1, the composition of gas is controlled to pass the aperture plate to generate neutral beam.

In Example 1, the aperture plate have apertures having a size of 1 mm×10 mm. in other embodiment of the present inventive concept, the aperture plate may have a desired physical characteristics, such as an aperture aspect ratio which may be more than 10.

The composition of gas is controlled at a pressure of 0.1 Pa to 1 Pa for the neutral beam to provide a desired kinetic energy.

After each surface of the two pieces of semiconductor materials is sufficiently irradiated by the neutral beam and an activated region of controlled thickness beneath the activated surfaces is then created, the two activated surfaces are introduced to contact to each other.

In Example 1, the activated surfaces contact to each other at a temperature from about 100° C. to 200° C. In other embodiments of the present inventive concept, the temperature may be no higher than about 200° C.

According to the present inventive concept, the contacted two pieces of semiconductor materials may be further pressed by machines.

### Comparative Example 1

In this comparative example, two pieces of semiconductor materials may be bonded by conventional plasma technology.

Following experimental section is to further describe the Example rather than limit it of the present inventive concept.

### Surface Energy

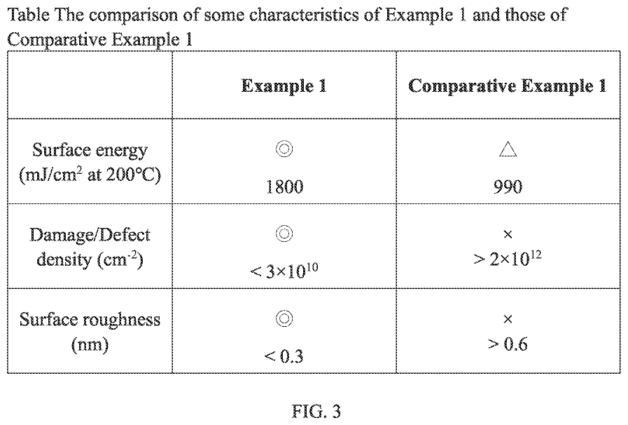

Please refer to FIG. 3 which is a table showing the comparison of some characteristics of Example 1 and those of Comparative Example 1.

According to the present inventive concept, Example 1 has surface energy almost two times higher than Comparative Example 1. High surface energy means a strong molecular attraction, while low surface energy means weaker attractive forces. In other words, the bonding strength of bonded layer structure of Example 1 achieved by the method of the present inventive concept is higher than that of Comparative Example 1 by the conventional plasma bonding technology.

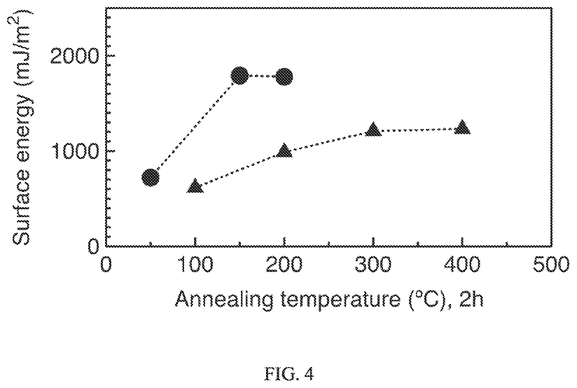

Further refer to FIG. 4 which shows the surface energy of an embodiment of the method of the present inventive concept and that of the comparative example at different temperature. Solid circle denotes the various embodiments of the present inventive concept bonded at different annealing temperature; and solid triangle denotes the comparative examples by the conventional plasma bonding technology.

According to FIG. 4, the method of the present inventive concept provides high surface energy at an annealing temperature from the room temperature to no higher than 200° C. The conventional plasma bonding technology does not achieve as high surface energy as the present inventive concept does at even higher annealing temperatures.

### Damage/Defect Density

Please refer to FIG. 3. The defect density of the Example 1 is <3×10¹⁰ which is two orders lower than that of Comparative Example 1.

### Surface Roughness

Further refer to FIG. 3. Example 1 activated by the neutral beams achieves smoother surface than Comparative Example 1. The surface roughness of Example 1 is less than 0.3 nm. On the other hand, the surface roughness of Comparative Example 1 is more than 0.6 nm.

### Example 2

In this example, a complementary field effect transistor (CFET) were prepared utilizing the method of the present inventive concept.

According to the present inventive concept, two layers of semiconductor materials of the CFET may be bonded by neutral beam technology provided by the method of the present inventive concept.

### Comparative Example

In this comparative example, a CFET may be bonded by conventional plasma technology.

Even high-density integration can be realized by the method of the present inventive concept. A vertically stacked triple-channel structure with 2 bottom Si layers and 1 top Ge layer has been demonstrated in Example 2, paving a path to achieve CMOS inverters with matching performance.

It is found out that SiOx deposited on Ge with TDMAS is suitable for the ALD layer compared to the Al₂O₃, since it can suppress the pattern width variation (ΔW).

The present inventive concept is able to provide a GaN PMOS and Silicon NMOS heterogeneous CFET for the single chip application in the 5G/6G single chip phone.

According to the present inventive concept, it is related to a defect-free neutral beam bonding technology at low temperature, which is able to combine and work on different substrates, which is able to reduce cost and form factor, and enables new hybrid circuit topologies to address performance and efficiency. The present inventive concept is believed to be a key enabler for the next-generation RF front-end modules beyond 5G/6G lower mm-wave bands for high power density.

The foregoing descriptions of the detailed embodiments are only illustrated to disclose the features and functions of the present inventive concept and not restrictive of the scope of the present inventive concept. It should be understood to those in the art that all modifications and variations according to the spirit and principle in the disclosure of the present inventive concept should fall within the scope of the appended claims.

What is claimed is:

1. A method of bonding two pieces of semiconductor materials, which comprises:
providing the two pieces of semiconductor materials each having a surface that is suitable for molecular bonding; and
activating at least one surface monolayer of one of the two pieces of semiconductor materials by irradiating neutral beam onto the surface(s) being activated while controlling activation parameters of the neutral beam to provide kinetic energy to the pieces sufficient to create an activated region of controlled thickness beneath the surface(s) being activated.

2. The method of claim 1, wherein the surface monolayer of each piece of semiconductor materials is activated by the neutral beam.

3. The method of claim 1, wherein the two pieces of semiconductor materials are made of different semiconductor materials.

4. The method of claim 1, wherein the controlling of the activation parameters obtains the activation of the surface(s) and creates the activated region in a predetermined thickness of the activated surface(s) and serves to control the maximum depth of the activated region in the surfaces.

5. The method of claim 4, wherein the activated region extends in the predetermined thickness of the piece(s) of semiconductor materials whose surface is being activated between a depth of 0.1 nm to 1 nm.

6. The method of claim 1, wherein the kinetic energy provided by the neutral beam is at a level of 10 eV to 200 eV.

7. The method of claim 1, wherein the controlling of the activation parameters comprises controlling kinetic energy by controlling plasma generation power and aperture bias power for the neutral beam to the surface(s) of the piece(s) of semiconductor materials.

8. The method of claim 7, wherein the controlling of the activation parameters comprises controlling kinetic energy by controlling the plasma generation power in a range between 500 W to 1500 W.

9. The method of claim 7, wherein the controlling of the activation parameters comprises controlling kinetic energy by controlling the aperture bias power in a range between 0 W to 30 W.

10. The method of claim 1, wherein the controlling of the activation parameters comprises controlling a composition of gas in which the neutral beam is generated to provide a desired kinetic energy.

11. The method of claim 10, wherein the gas is at least one selected from a group consisting of oxygen, nitrogen, hydrogen and rare gas.

12. The method of claim 11, wherein the rare gas comprises argon, xenon, or krypton.

13. The method of claim 10, wherein the controlling of the activation parameters comprises controlling the composition of gas passing an aperture plate to generate neutral beam.

14. The method of claim 13, wherein the aperture plate has an aperture aspect ratio which is more than 10.

15. The method of claim 13, wherein the aperture plate has a size of 1 mm×10 mm.

16. The method of claim 10, wherein the controlling of the activation parameters comprises controlling the composition of gas at a pressure of 0.1 Pa to 1 Pa for the neutral beam to provide a desired kinetic energy.

17. The method of claim 1, wherein the controlling of the activation parameters is implemented in order to create a single activated region in a predetermined thickness of the surface region of the piece(s) of semiconductor materials whose surface is being activated.

18. The method of claim 1, further comprising:
introducing the activated surfaces to contact to each other.

19. The method of claim 18, wherein the activated surfaces contact to each other at a temperature of no higher than about 200° C.

20. The method of claim 19, wherein the temperature is from about 100° C. to 200° C.

21. The method of claim 1, further comprising:
conducting wet surface modification at least on the surface(s) of the two pieces of semiconductor materials before the step of activating at least one surface monolayer of one of the two pieces of semiconductor materials by irradiating neutral beam onto the surface(s).

22. A structure formed according to the method of claim 1.
